(19) United States
(12) Patent Application Publication
(10) Pub. No.: US 2024/0235519 A1
(43) Pub. Date: Jul. 11, 2024

(54) ACOUSTIC WAVE DEVICE AND METHOD FOR MANUFACTURING ACOUSTIC WAVE DEVICE

(71) Applicant: Murata Manufacturing Co., Ltd., Nagaokakyo-shi (JP)

(72) Inventor: Kazunori INOUE, Nagaokakyo-shi (JP)

(21) Appl. No.: 18/613,799

(22) Filed: Mar. 22, 2024

Related U.S. Application Data
(63) Continuation of application No. PCT/JP2022/037655, filed on Oct. 7, 2022.
(60) Provisional application No. 63/253,599, filed on Oct. 8, 2021.

(51) Int. Cl. H03H 9/02; H03H 3/04; H03H 9/145

(52) U.S. Cl. CPC H03H 9/02574; H03H 3/04; H03H 9/02015; H03H 9/02062; H03H 9/14541; H03H 2003/0435; H03H 9/02637

(57) ABSTRACT

An acoustic wave device includes a support substrate including a hollow portion, a piezoelectric layer laminated on the support substrate and including a membrane portion at least partially overlapping the hollow portion in a lamination direction, and an electrode on the piezoelectric layer. The electrode includes an IDT electrode finger and an electrode portion other than the IDT electrode finger. The IDT electrode finger is provided on the membrane portion, and an outer contour of the electrode portion intersects with a boundary of the membrane portion in plan view.

### CROSS REFERENCE TO RELATED APPLICATIONS

This application claims the benefit of priority to Provisional Application No. 63/253,599 filed on Oct. 8, 2021 and is a Continuation Application of PCT Application No. PCT/JP2022/037655 filed on Oct. 7, 2022. The entire contents of each application are hereby incorporated herein by reference.

### BACKGROUND OF THE INVENTION

### 1. Field of the Invention

The present disclosure relates to acoustic wave devices each including a piezoelectric layer.

### 2. Description of the Related Art

For example, Japanese Unexamined Patent Application Publication No. 2012-257019 discloses an acoustic wave device utilizing a plate wave. The acoustic wave device described in Japanese Unexamined Patent Application Publication No. 2012-257019 includes a support, a piezoelectric substrate, and an interdigital transducer (IDT) electrode. The support is provided with a hollow portion. The piezoelectric substrate is provided on the supporter to overlap the hollow portion. The IDT electrode is provided on the piezoelectric substrate to overlap the hollow portion. In the acoustic wave device, a plate wave is excited by the IDT electrode. The edge portion of the hollow portion does not include a linear portion extending in parallel to the propagation direction of the plate wave excited by the IDT electrode.

### SUMMARY OF THE INVENTION

In recent years, an acoustic wave device capable of preventing cracks in a membrane portion has been demanded.

Example embodiments of the present invention provide acoustic wave devices each capable of preventing a crack in a membrane portion.

An acoustic wave device according to an example embodiment of the present disclosure includes a support substrate including a hollow portion, a piezoelectric layer laminated on the support substrate and including a membrane portion at least partially overlapping the hollow portion in the lamination direction, and an electrode provided on the piezoelectric layer, in which the electrode includes an IDT electrode finger and an electrode portion other than the IDT electrode finger, the IDT electrode finger is provided on the membrane portion, and an outer contour of the electrode portion intersects with a boundary of the membrane portion in plan view.

According to example embodiments of the present disclosure, acoustic wave devices each capable of preventing a crack in a membrane portion are provided.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is a schematic perspective view illustrating an external appearance of an acoustic wave device of first and second aspects of example embodiments of the present invention.

FIG. 1B is a plan view illustrating an electrode structure on a piezoelectric layer.

FIG. 2 is a cross-sectional view of a portion taken along a line A-A in FIG. 1A.

FIG. 3A is a schematic elevational cross-sectional view for explaining a Lamb wave propagating through a piezoelectric film of a known acoustic wave device.

FIG. 3B is a schematic elevational cross-sectional view for explaining a wave of an acoustic wave device according to an example embodiment of the present invention.

FIG. 4 is a schematic diagram illustrating a bulk wave when a voltage is applied between a first electrode and a second electrode in such a manner that a potential of the second electrode is higher than a potential of the first electrode.

FIG. 5 is a diagram depicting resonance characteristics of an acoustic wave device according to a first example embodiment of the present invention.

FIG. 6 is a diagram depicting a relationship between d/2p and a fractional bandwidth as a resonator of an acoustic wave device.

FIG. 7 is a plan view of another acoustic wave device according to the first example embodiment of the present invention.

FIG. 8 is a reference diagram depicting an example of resonance characteristics of an acoustic wave device.

FIG. 9 is a diagram depicting a relationship between a fractional bandwidth and a phase rotation quantity of spurious impedance normalized by 180 degrees as magnitude of a spurious emission in a case where a large number of acoustic wave resonators are provided.

FIG. 10 is a diagram depicting a relationship between d/2p, a metalization ratio MR, and a fractional bandwidth.

FIG. 11 is a diagram depicting a map of a fractional bandwidth with respect to Euler angles (0°, θ, ψ) of LiNbO₃ in a case where d/p is made to approach 0 as much as possible.

FIG. 12 is a partially cutaway perspective view for explaining an acoustic wave device according to the first example embodiment of the present invention.

FIG. 13 is a plan view illustrating an acoustic wave device of a second example embodiment of the present invention.

FIG. 14 is a cross-sectional view taken along a line XIV-XIV in FIG. 13.

FIG. 15 is a cross-sectional view taken along a line XV-XV in FIG. 13.

FIG. 16 is a cross-sectional view taken along a line XVI-XVI in FIG. 13.

FIG. 17 is a plan view illustrating a first modification of the acoustic wave device in FIG. 13.

FIG. 18 is a cross-sectional view taken along a line XVIII-XVIII in FIG. 17.

FIG. 19 is a cross-sectional view taken along a line XIX-XIX in FIG. 17.

FIG. 20 is a cross-sectional view taken along a line XX-XX in FIG. 17.

FIG. 21 is a plan view illustrating a second modification of the acoustic wave device in FIG. 13.

FIG. 22 is a cross-sectional view taken along a line XXII-XXII in FIG. 21.

FIG. 23 is a cross-sectional view taken along a line XXIII-XXIII in FIG. 21.

FIG. 24 is a plan view of an acoustic wave device in which an outer contour of an electrode portion other than an IDT electrode finger does not intersect with a boundary of a membrane portion in plan view.

FIG. 25 is a cross-sectional view taken along a line XXV-XXV in FIG. 24.

FIG. 26 is a cross-sectional view taken along a line XXVI-XXVI in FIG. 24.

FIG. 27 is a cross-sectional view taken along a line XXVII-XXVII in FIG. 24.

### DETAILED DESCRIPTION OF THE EXAMPLE EMBODIMENTS

Acoustic wave devices of first, second, and third aspects of example embodiments of the present disclosure each include, for example, a piezoelectric layer made of lithium niobate or lithium tantalate, and a first electrode and a second electrode facing each other in a direction intersecting a thickness direction of the piezoelectric layer.

The acoustic wave device of the first aspect of an example embodiment of the present invention utilizes a bulk wave in a thickness-shear primary mode.

In the acoustic wave device of the second aspect of an example embodiment of the present invention, the first electrode and the second electrode are adjacent electrodes, and d/p is about 0.5 or less, where d is a thickness of the piezoelectric layer and p is a center-to-center distance between the first electrode and the second electrode. Thus, in the first and second aspects of example embodiments of the present invention, a Q value can be increased even when miniaturization is advanced.

The acoustic wave device of the third aspect of an example embodiment of the present invention utilizes a Lamb wave as a plate wave. Resonance characteristics generated by the Lamb wave can be obtained.

An acoustic wave device of a fourth aspect of an example embodiment of the present disclosure includes a piezoelectric layer made of lithium niobate or lithium tantalate, and an upper electrode and a lower electrode opposing each other interposing the piezoelectric layer therebetween in the thickness direction of the piezoelectric layer, and utilizes a bulk wave.

Hereinafter, the present disclosure will be clarified by describing specific example embodiments of the acoustic wave devices of the first to fourth aspects with reference to the drawings.

It is to be noted that the example embodiments described in the present specification are merely examples, and partial replacement or combination of the configurations can be carried out between the different example embodiments.

### First Example Embodiment

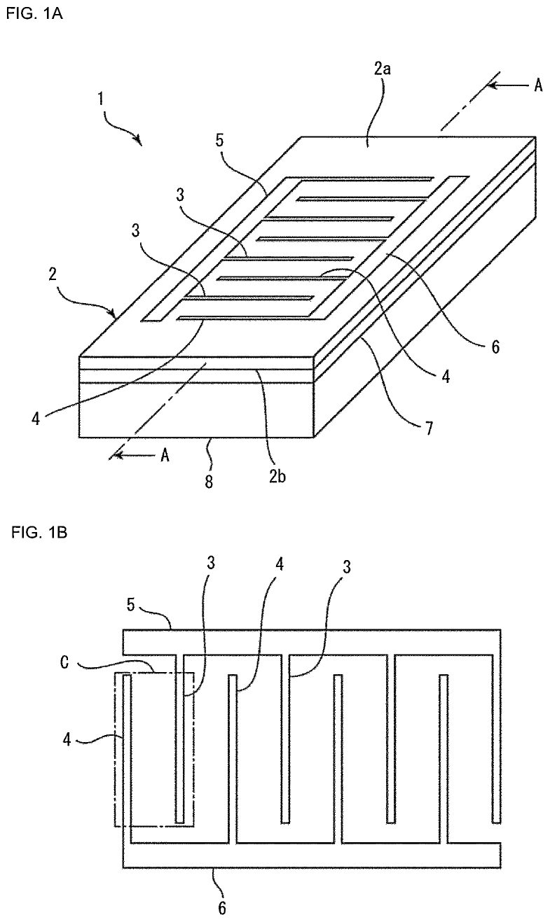

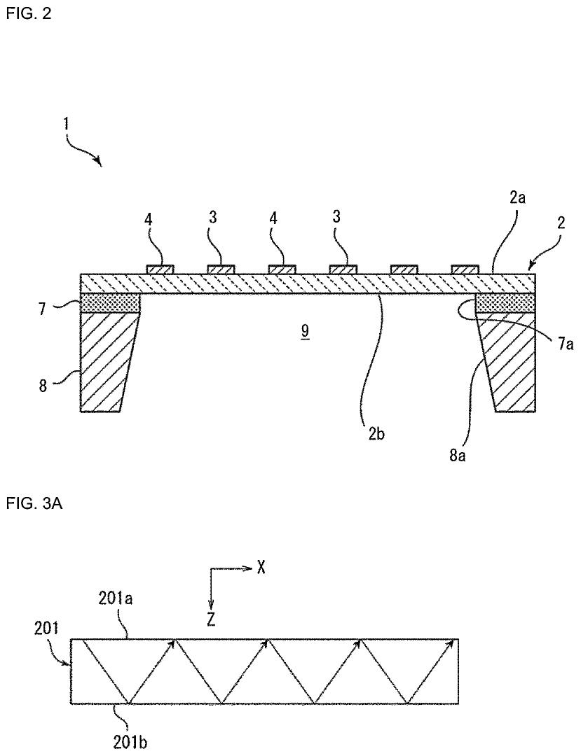

FIG. 1A is a schematic perspective view illustrating an external appearance of an acoustic wave device according to a first example embodiment regarding the first and second aspects, FIG. 1B is a plan view illustrating an electrode structure on a piezoelectric layer, and FIG. 2 is a cross-sectional view of a portion taken along a line A-A in FIG. 1A.

An acoustic wave device 1 includes a piezoelectric layer 2 made of LiNbO₃. The piezoelectric layer 2 may be made of LiTaO₃. The cut-angles of the LiNbO₃ and LiTaO₃ are a Z-cut in the present example embodiment, but may be a rotated Y-cut or X-cut. A propagation orientation of ±30° of the Y propagation and X propagation is preferred, for example. The thickness of the piezoelectric layer 2 is not particularly limited, but is preferably about 50 nm or more and about 1000 nm or less in order to effectively excite the thickness-shear primary mode, for example.

The piezoelectric layer 2 includes first and second principal surfaces 2a and 2b opposing each other. Electrodes 3 and 4 are provided on the first principal surface 2a. The electrode 3 is an example of the “first electrode”, and the electrode 4 is an example of the “second electrode”. In FIGS. 1A and 1B, a plurality of the electrodes 3 is a plurality of first electrode fingers connected to a first busbar 5. A plurality of the electrodes 4 is a plurality of second electrode fingers connected to a second busbar 6. The plurality of electrodes 3 and the plurality of electrodes 4 interdigitate with each other.

The electrodes 3 and 4 may have a rectangular or substantially rectangular shape and extend in a longitudinal direction. The electrode 3 and the adjacent electrode 4 face each other in a direction orthogonal to the longitudinal direction. The plurality of electrodes 3, the plurality of electrodes 4, the first busbar 5, and the second busbar 6 define an interdigital transducer (IDT) electrode. The longitudinal direction of the electrodes 3 and 4 and the direction orthogonal to the longitudinal direction of the electrodes 3 and 4 are both directions intersecting the thickness direction of the piezoelectric layer 2. Therefore, it can be said that the electrode 3 and the adjacent electrode 4 face each other in a direction intersecting the thickness direction of the piezoelectric layer 2.

The longitudinal direction of the electrodes 3 and 4 may be interchanged with the direction orthogonal to the longitudinal direction of the electrodes 3 and 4 illustrated in FIGS. 1A and 1B. That is, in FIGS. 1A and 1B, the electrodes 3 and 4 may extend in the direction in which the first busbar 5 and the second busbar 6 extend. In this case, the first busbar 5 and the second busbar 6 extend in the direction in which the electrodes 3 and 4 extend in FIGS. 1A and 1B.

A plurality of structures each including a pair of electrodes including the electrode 3 connected to one potential and the electrode 4 connected to the other potential adjacent to each other is provided in a direction orthogonal to the longitudinal direction of the electrodes 3 and 4. In this case, “the electrode 3 and the electrode 4 are adjacent to each other” does not mean that the electrode 3 and the electrode 4 are in direct contact with each other, but means that the electrode 3 and the electrode 4 are positioned with a gap interposed therebetween.

When the electrode 3 and the electrode 4 are adjacent to each other, none of the electrodes including the other electrodes 3 and 4 connected to a hot electrode, a ground electrode, or the like are provided between the electrode 3 and the electrode 4. The number of pairs of electrodes is not limited to an integer, and may be 1.5, 2.5, or the like. The center-to-center distance between the electrodes 3 and 4, that is, the pitch therebetween is preferably in a range from about 1 μm to about 10 μm, for example. The center-to-center distance between the electrodes 3 and 4 is a distance between the center of a width dimension of the electrode 3 in the direction orthogonal to the longitudinal direction of the electrode 3 and the center of a width dimension of the electrode 4 in the direction orthogonal to the longitudinal direction of the electrode 4. In a case where at least one of the electrodes 3 and 4 is allowed to be provided plurally (in a case where 1.5 or more pairs of electrodes are provided while taking a pair of electrodes 3 and 4 as a pair of electrodes), the center-to-center distance between the electrodes 3 and 4 refers to an average value of the respective center-to-center distances between the adjacent electrodes 3 and 4 among the 1.5 or more pairs of electrodes 3 and 4. The widths of the electrodes 3 and 4, that is, the dimensions in the facing direction of the electrodes 3 and 4 are preferably in a range from about 150 nm to about 1000 nm, for example. The center-to-center distance between the electrodes 3 and 4 is a distance between the center of the dimension (width dimension) of the electrode 3 in the direction orthogonal to the longitudinal direction of the electrode 3 and the center of the dimension (width dimension) of the electrode 4 in the direction orthogonal to the longitudinal direction of the electrode 4.

In the present example embodiment, since the Z-cut piezoelectric layer is used, the direction orthogonal to the longitudinal direction of the electrodes 3 and 4 is a direction orthogonal to a polarization direction of the piezoelectric layer 2. This is not the case when a piezoelectric material with another cut-angle is used as the piezoelectric layer 2. Here, the term “orthogonal” is not limited only to a case of being strictly orthogonal, and is allowed to be substantially orthogonal (an angle formed between the direction orthogonal to the longitudinal direction of the electrodes 3 and 4 and the polarization direction is, for example, about 90°±10°).

A support 8 is laminated on the second principal surface 2b side of the piezoelectric layer 2 with an insulating layer (also referred to as a bonding layer) 7 interposed therebetween. The insulating layer 7 and the support 8 have a frame shape and include cavities 7a and 8a, as illustrated in FIG. 2. Thus, a hollow portion 9 is provided. The hollow portion 9 is provided not to hinder vibrations of an excitation region C of the piezoelectric layer 2. Accordingly, the support 8 is laminated on the second principal surface 2b with the insulating layer 7 interposed therebetween at a position not overlapping a portion where at least one pair of electrodes 3 and 4 is provided. The insulating layer 7 need not be provided. Therefore, the support 8 can be directly or indirectly laminated on the second principal surface 2b of the piezoelectric layer 2.

The insulating layer 7 is made of silicon oxide. Note that an appropriate insulating material such as silicon oxynitride or alumina may be used other than silicon oxide. The support 8 is made of Si. The plane orientation of a surface of the Si on the piezoelectric layer 2 side may be (100), (110), or (111). Preferably, high-resistance Si having a resistivity of about 4 kS) or more is used, for example. Note that the support 8 may be formed using an appropriate insulating material or semiconductor material. As the material of the support 8, for example, a piezoelectric material such as aluminum oxide, lithium tantalate, lithium niobate or quartz, various ceramics such as alumina, magnesia, sapphire, silicon nitride, aluminum nitride, silicon carbide, zirconia, cordierite, mullite, steatite or forsterite, a dielectric such as diamond or glass, or a semiconductor such as gallium nitride may be used.

The plurality of electrodes 3 and 4 and the first and second busbars 5 and 6 are made of suitable metals or alloys such as Al or an AlCu alloy. In the present example embodiment, the electrodes 3 and 4 and the first and second busbars 5 and 6 each have a structure in which an Al film is laminated on a Ti film. Note that a close contact layer other than the Ti film may be used.

At the time of driving, an AC voltage is applied between the plurality of electrodes 3 and the plurality of electrodes 4. More specifically, an AC voltage is applied between the first busbar 5 and the second busbar 6. This makes it possible to obtain resonance characteristics utilizing a bulk wave in a thickness-shear primary mode excited in the piezoelectric layer 2.

In the acoustic wave device 1, d/p is about 0.5 or less, where d is the thickness of the piezoelectric layer 2 and p is the center-to-center distance between any adjacent electrodes 3 and 4 among the plurality of pairs of electrodes 3 and 4. Due to this, the bulk wave in the thickness-shear primary mode is effectively excited, and favorable resonance characteristics can be obtained. More preferably, d/p is about 0.24 or less, and in this case, even more favorable resonance characteristics can be obtained.

As in the present example embodiment, in the case where at least one of the electrodes 3 and 4 is allowed to be provided plurally, that is, in the case where 1.5 or more pairs of electrodes 3 and 4 are provided while taking the electrodes 3 and 4 as a pair of electrodes, the center-to-center distance p between the electrodes 3 and 4 adjacent to each other refers to an average distance of the respective center-to-center distances between the adjacent electrodes 3 and 4.

The acoustic wave device 1 of the present example embodiment has the above-described configuration, whereby a decrease in the Q value is unlikely to occur even when the number of pairs of electrodes 3 and 4 is decreased to achieve a reduction in size. This is because the resonator is such a resonator that does not need reflectors at both sides thereof and propagation loss is small. Since the bulk wave in the thickness-shear primary mode is utilized, the above-mentioned reflectors are not needed.

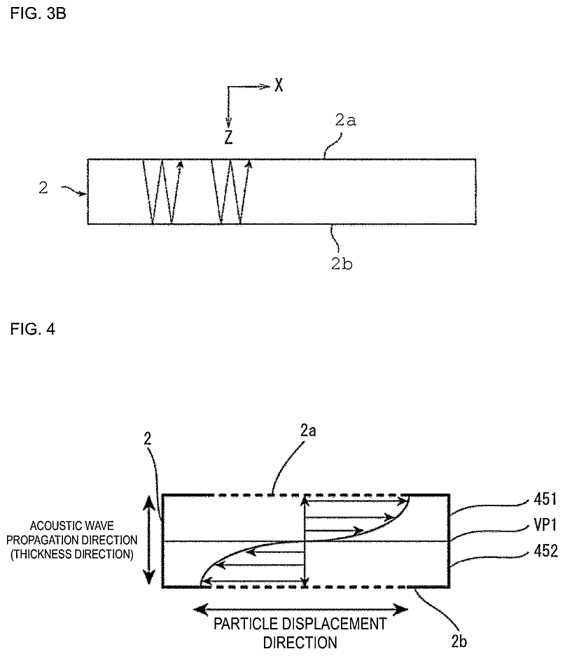

A difference between a Lamb wave utilized in a known acoustic wave device and the bulk wave in the thickness-shear primary mode will be described with reference to FIGS. 3A and 3B.

FIG. 3A is a schematic elevational cross-sectional view for explaining a Lamb wave propagating through a piezoelectric film of a known acoustic wave device. A known acoustic wave device is described in, for example, Japanese Unexamined Patent Application Publication No. 2012-257019. As illustrated in FIG. 3A, in the known acoustic wave device, a wave propagates in a piezoelectric film 201 as indicated by arrows. In the piezoelectric film 201, a first principal surface 201a and a second principal surface 201b oppose each other, and a thickness direction connecting the first principal surface 201a and the second principal surface 201b is a Z direction. An X direction is a direction in which the electrode fingers of the IDT electrode are aligned. As illustrated in FIG. 3A, in the case of the Lamb wave, the wave propagates in the X direction as depicted in the drawing. Although the piezoelectric film 201 vibrates as a whole because the wave is a plate wave, the wave propagates in the X direction, and thus reflectors are provided at both sides to obtain resonance characteristics. This causes propagation loss of the wave, and when it is attempted to achieve the miniaturization, that is, when the number of pairs of electrode fingers is reduced, the Q value is lowered.

In contrast, as illustrated in FIG. 3B, in the acoustic wave device 1 of the present example embodiment, since the vibration is displaced in a thickness-shear direction, the wave propagates in a direction connecting the first principal surface 2a and the second principal surface 2b of the piezoelectric layer 2, that is, substantially propagates in the Z direction, and resonates. That is, the X-direction component of the wave is significantly smaller than the Z-direction component thereof. Since the resonance characteristics are obtained by the propagation of the wave in the Z direction, no reflector is needed. Accordingly, the propagation loss caused when the wave propagates to the reflector does not occur. Therefore, even in a case where the number of pairs of electrodes of the electrodes 3 and 4 is decreased to achieve a reduction in size, a decrease in the Q value is unlikely to occur.

As illustrated in FIG. 4, an amplitude direction of a bulk wave in the thickness-shear primary mode is reversed between a first region 451 included in the excitation region C of the piezoelectric layer 2 and a second region 452 included in the excitation region C thereof. FIG. 4 schematically illustrates the bulk wave when a voltage is applied between the electrode 3 and the electrode 4 in such a manner that a potential of the electrode 4 is higher than a potential of the electrode 3. In the excitation region C, the first region 451 is a region between the first principal surface 2a and a virtual plane VP1 being orthogonal to the thickness direction of the piezoelectric layer 2 and dividing the piezoelectric layer 2 into two parts. In the excitation region C, the second region 452 is a region between the virtual plane VP1 and the second principal surface 2b.

As described above, in the acoustic wave device 1, at least one pair of electrodes of the electrodes 3 and 4 is provided, but the purpose is not to propagate the wave in the X direction. Therefore, it is not absolutely necessary that the number of pairs of electrodes of the electrodes 3 and 4 is plural. In other words, it is only necessary to provide at least one pair of electrodes.

For example, the electrode 3 is an electrode connected to a hot potential, and the electrode 4 is an electrode connected to a ground potential. However, the electrode 3 may be connected to the ground potential, and the electrode 4 may be connected to the hot potential. In the present example embodiment, as described above, at least one pair of electrodes refers to electrodes connected to the hot potential or electrodes connected to the ground potential, and no floating electrode is provided.

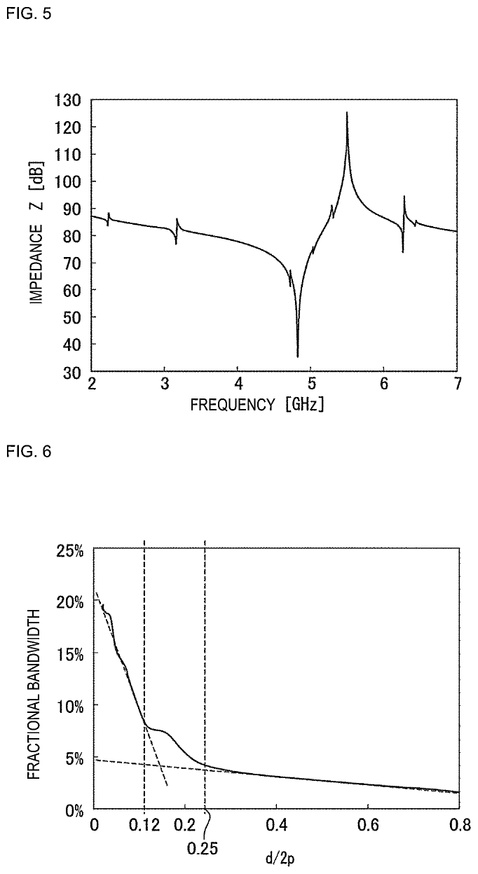

FIG. 5 is a diagram depicting resonance characteristics of the acoustic wave device according to the first example embodiment of the present disclosure. Example design parameters of the acoustic wave device 1 having the depicted resonance characteristics are as follows.
Piezoelectric layer 2: LiNbO₃ with Euler angles (0°, 0°, 90°), thickness=400 nm.

When viewed in a direction orthogonal to the longitudinal direction of the electrodes 3 and 4, the length of a region where the electrodes 3 and 4 overlap each other, i.e., the length of the excitation region C is 40 μpm, the number of pairs of electrodes of the electrodes 3 and 4 is 21, the center-to-center distance between the electrodes is 3 μm, the width of the electrodes 3 and 4 is 500 nm, and d/p is 0.133.
Insulating layer 7: a silicon oxide film having a thickness of 1 μm.
Support 8: Si.

The length of the excitation region C refers to a dimension of the excitation region C along the longitudinal direction of the electrodes 3 and 4.

In the present example embodiment, the distance between the electrodes of the pair of electrodes of the electrodes 3 and 4 was made equal across all of the plurality of pairs. That is, the electrodes 3 and the electrodes 4 were positioned at an equal pitch.

As is clear from FIG. 5, although no reflector is provided, favorable resonance characteristics with a fractional bandwidth being about 12.5% are obtained, for example.

As described above, in the present example embodiment, d/p is about 0.5 or less, and more preferably is about 0.24 or less, where d is the thickness of the piezoelectric layer 2 and p is the center-to-center distance between the electrodes 3 and 4. This will be described with reference to FIG. 6.

Similar to the acoustic wave device having obtained the resonance characteristics depicted in FIG. 5, a plurality of the acoustic wave devices was achieved through changing d/2p. FIG. 6 is a diagram depicting a relationship between the above-mentioned d/2p and a fractional bandwidth as a resonator of the acoustic wave device.

As is clear from FIG. 6, when d/2p exceeds about 0.25, i.e., when d/p is greater than about 0.5, the fractional bandwidth is less than about 5% even when d/p is adjusted, for example. In contrast, when d/2p 0.25, i.e., d/p 0.5, the fractional bandwidth can be increased to about 5% or more by changing d/p within the above range, that is, a resonator having a high coupling coefficient can be provided. When d/2p is about 0.12 or less, i.e., when d/p is about 0.24 or less, the fractional bandwidth can be increased to about 7% or more, for example. In addition, when d/p is adjusted within this range, a resonator having a wider fractional bandwidth can be obtained, and a resonator having a higher coupling coefficient can be achieved. Accordingly, it was discovered and confirmed that, by setting d/p to be equal to or smaller than about 0.5 as in the acoustic wave device of the second aspect of an example embodiment of the present disclosure, a resonator having a high coupling coefficient utilizing the bulk wave in the thickness-shear primary mode can be provided.

As described above, at least a pair of electrodes may be one pair, and the above-mentioned p is the center-to-center distance between the adjacent electrodes 3 and 4 in the case of one pair of electrodes. In the case of 1.5 or more pairs of electrodes, it is sufficient that the average distance of the respective center-to-center distances between the adjacent electrodes 3 and 4 is taken as p.

As for the thickness d of the piezoelectric layer, in the case where there is a variation in thickness of the piezoelectric layer 2, it is sufficient to adopt a value obtained by averaging the thicknesses thereof.

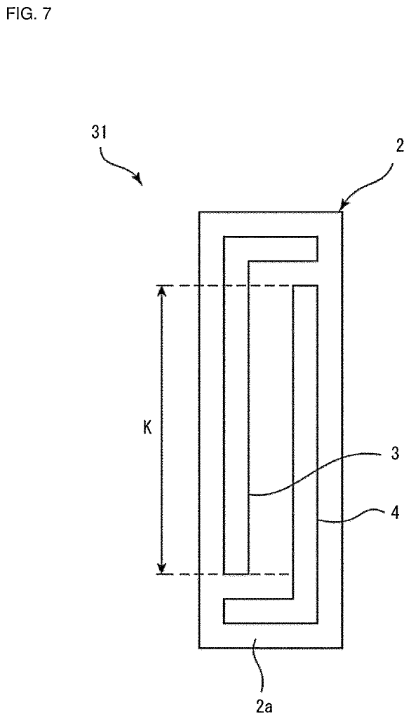

FIG. 7 is a plan view of another acoustic wave device according to the first example embodiment of the present disclosure. In an acoustic wave device 31, a pair of electrodes including electrodes 3 and 4 is provided on a first principal surface 2a of a piezoelectric layer 2. Note that K in FIG. 7 is an overlap width. As described above, in the acoustic wave device 31 of the present disclosure, the number of pairs of electrodes may be one. In this case as well, when the above-mentioned d/p is equal to or less than about 0.5, a bulk wave in the thickness-shear primary mode can be effectively excited.

In the acoustic wave device 1, it is desirable that, with respect to an excitation region where any adjacent electrodes 3 and 4 among the plurality of electrodes 3 and electrodes 4 overlap each other when viewed in the direction in which the above adjacent electrodes 3 and 4 face each other, a metalization ratio MR of the above adjacent electrodes 3 and 4 satisfies a relation of MR≤about 1.75(d/p)+0.075, for example. That is, when viewed in the direction in which the plurality of first electrode fingers and the plurality of second electrode fingers adjacent to each other face each other, a region in which the plurality of first electrode fingers and the plurality of second electrode fingers overlap each other is an excitation region (overlap region). When the metalization ratio of the plurality of first electrode fingers and the plurality of second electrode fingers with respect to the excitation region is represented by MR, it is preferable to satisfy the relation of MR≤about 1.75(d/p)+0.075, for example. In this case, a spurious emission may be effectively reduced.

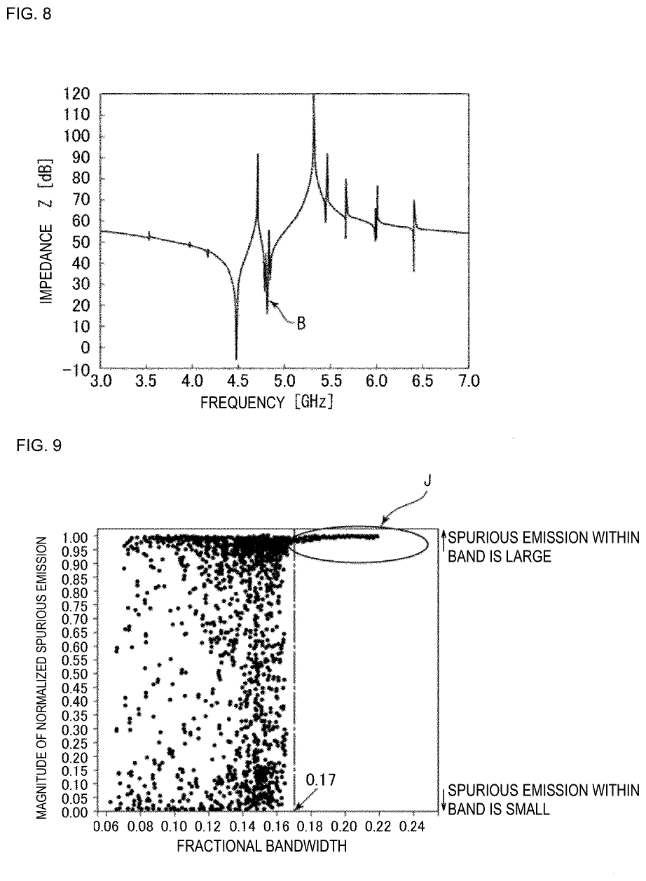

This will be described with reference to FIGS. 8 and 9. FIG. 8 is a reference diagram depicting an example of the resonance characteristics of the acoustic wave device 1. A spurious emission indicated by an arrow B appears between a resonant frequency and an anti-resonant frequency. Note that d/p was equal to about 0.08 and Euler angles of LiNbO₃ were (0°, 0°, 90°), for example. The metalization ratio MR was set to about 0.35, for example.

The metalization ratio MR will be explained with reference to FIG. 1B. In the electrode structure illustrated in FIG. 1B, when a certain pair of electrodes 3 and 4 is focused on, it is considered that only this pair of electrodes 3 and 4 is provided. In this case, a section surrounded by a chain line C is an excitation region. When the electrode 3 and the electrode 4 are viewed in a direction orthogonal to the longitudinal direction of the electrodes 3 and 4, that is, viewed in the facing direction, the excitation region refers to a region in the electrode 3 that overlaps the electrode 4, a region in the electrode 4 that overlaps the electrode 3, and a region between the electrode 3 and the electrode 4 where the electrode 3 and the electrode 4 overlap each other. Then, the ratio of the area of the electrodes 3 and 4 in the excitation region C to the area of the excitation region is the metalization ratio MR. That is, the metalization ratio MR is the ratio of the area of a metalization portion to the area of the excitation region.

When a plurality of pairs of electrodes is provided, it is sufficient that the ratio of the metalization portion included in the entire excitation region to the total area of the excitation region is defined as MR.

In accordance with the present example embodiment, FIG. 9 is a diagram depicting a relationship between a fractional bandwidth and a phase rotation quantity of spurious impedance normalized by 180 degrees as magnitude of a spurious emission in a case where a large number of acoustic wave resonators are provided. The fractional bandwidth was adjusted by variously changing the thickness of the piezoelectric layer, the dimensions of the electrodes, and the like. FIG. 9 depicts a result obtained when a piezoelectric layer made of Z-cut LiNbO₃ is used, but the same tendency is obtained when a piezoelectric layer with another cut-angle is used.

In a region surrounded by an ellipse J in FIG. 9, a spurious emission is increased to be about 1.0, for example. As is clear from FIG. 9, in a case where the fractional bandwidth exceeds about 0.17, that is, when the fractional bandwidth exceeds about 17%, for example, a large spurious emission having a spurious level of 1 or more appears in a pass band even when parameters defining the fractional bandwidth are changed. That is, as in the resonance characteristics depicted in FIG. 8, a large spurious emission indicated by the arrow B appears within the band. Accordingly, the fractional bandwidth is preferably about 17% or less, for example. In this case, the spurious emission may be reduced by adjusting the thickness of the piezoelectric layer 2, the dimensions of the electrodes 3 and 4, or the like.

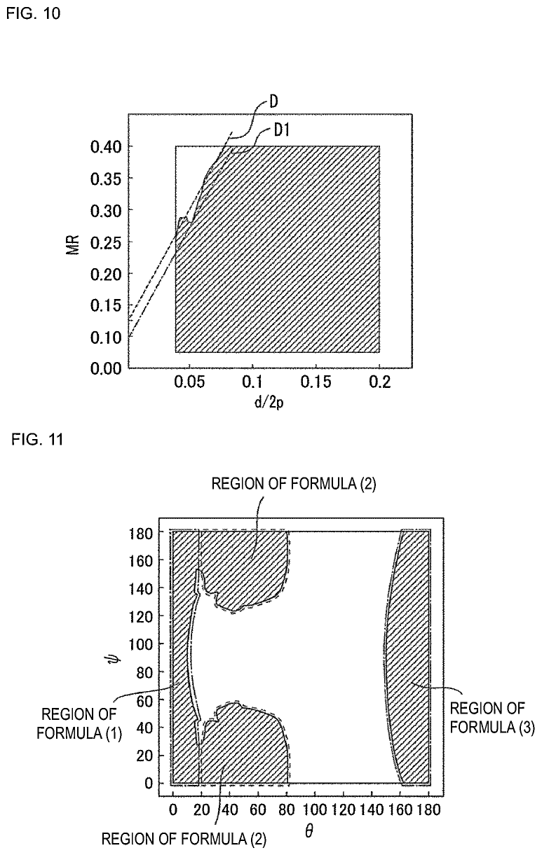

FIG. 10 is a diagram depicting a relationship between d/2p, a metalization ratio MR, and a fractional bandwidth. In the above-discussed acoustic wave device, various acoustic wave devices having different values of d/2p and MR were provided, and the fractional bandwidths were measured. A hatched portion on the right side of a broken line D in FIG. 10 is a region where the fractional bandwidth is about 17% or less, for example. A boundary between the hatched region and the unhatched region is represented by an expression of MR=about 3.5(d/2p)−0.075. That is, MR is equal to about 1.75(d/p)+0.075, for example. Accordingly, the following relation is preferably satisfied: MR≤about 1.75(d/p)+0.075, for example. In this case, the fractional bandwidth is easily set to about 17% or less, for example. More preferred is a region on the right side of an expression of MR=about 3.5(d/2p)+0.05, which is indicated by a chain line D1 in FIG. 10. That is, when a relation of MR≤about 1.75(d/p)+0.05 is satisfied, the fractional bandwidth can be reliably set to about 17% or less, for example.

FIG. 11 is a diagram depicting a map of a fractional bandwidth with respect to Euler angles (0°, θ, ψ) of LiNbO₃ in a case where d/p is made to approach 0 as much as possible. A hatched portion in FIG. 11 is a region where a fractional bandwidth of at least about 5% or more is obtained. When the range of the region is approximated, obtained are ranges represented by Formula (1), Formula (2), and Formula (3).

(0°±10°, 0° to 20°, optional ψ) Formula (1)

(0°±10°, 20° to 80°, 0° to 60° (1−(θ−50)²/900)^{1/2}) or (0°±10°, 20° to 80°, [180°−60° (1−(θ−50)²/900)^{1/2}] to 180°) Formula (2)

(0°±10°, [180°−30° (1−(ψ−90)²/8100)^{1/2}] to 180°, optional ψ) Formula (3)

Therefore, the above-described Euler angles range of Formula (1), (2), or (3) is preferred because the fractional bandwidth can be sufficiently widened.

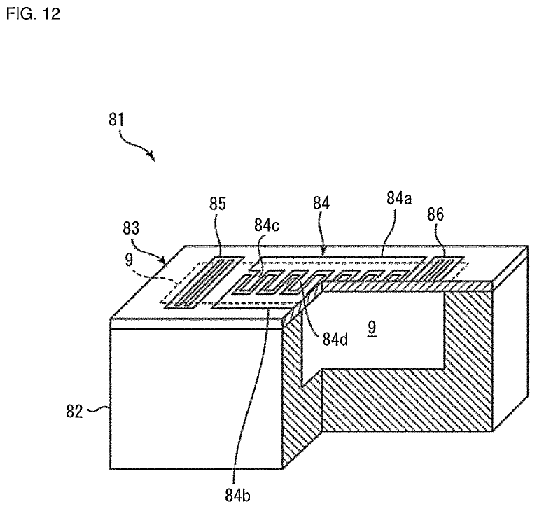

FIG. 12 is a partially cutaway perspective view for explaining an acoustic wave device according to the first example embodiment of the present disclosure. An acoustic wave device 81 includes a support substrate 82. The support substrate 82 is provided with a recess opened to an upper surface. A piezoelectric layer 83 is laminated on the support substrate 82. With this, a hollow portion 9 is provided. An IDT electrode 84 is provided on the piezoelectric layer 83 above the hollow portion 9. Reflectors 85 and 86 are provided at both sides in the acoustic wave propagation direction of the IDT electrode 84. In FIG. 12, an outer peripheral edge of the hollow portion 9 is indicated by a broken line. In this case, the IDT electrode 84 includes first and second busbars 84a and 84b, a plurality of electrodes 84c as first electrode fingers, and a plurality of electrodes 84d as second electrode fingers. The plurality of electrodes 84c is connected to the first busbar 84a. The plurality of electrodes 84d is connected to the second busbar 84b. The plurality of electrodes 84c and the plurality of electrodes 84d interdigitate with each other.

In the acoustic wave device 81, an AC electric field is applied to the IDT electrode 84 above the hollow portion 9 to excite a Lamb wave as a plate wave. Since the reflectors 85 and 86 are provided at both the sides, resonance characteristics generated by the Lamb wave can be obtained.

As described above, an acoustic wave device according to an example embodiment of the present disclosure may utilize a plate wave.

### Second Example Embodiment

An acoustic wave device 1 of a second example embodiment will be described below. In the second example embodiment, description of the same contents as those in the first example embodiment will be omitted as appropriate. The contents described in the first example embodiment can be applied to the second example embodiment.

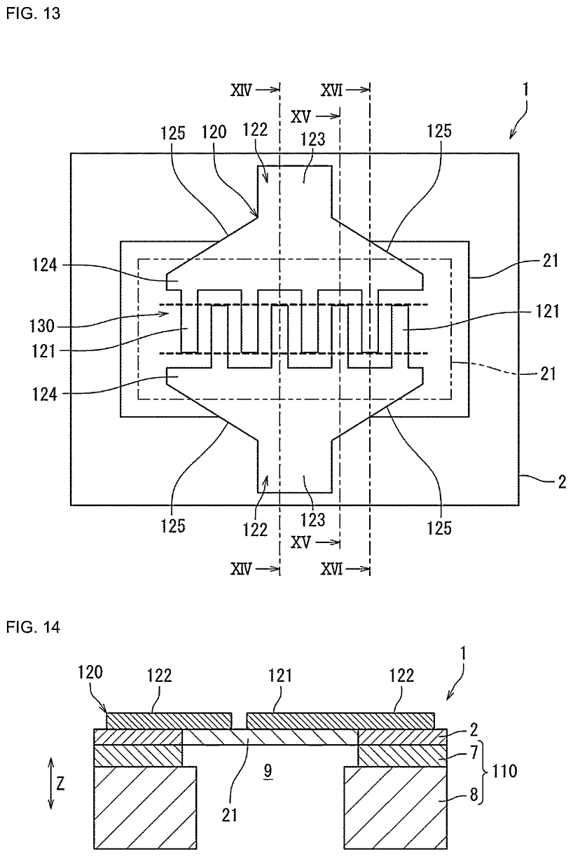

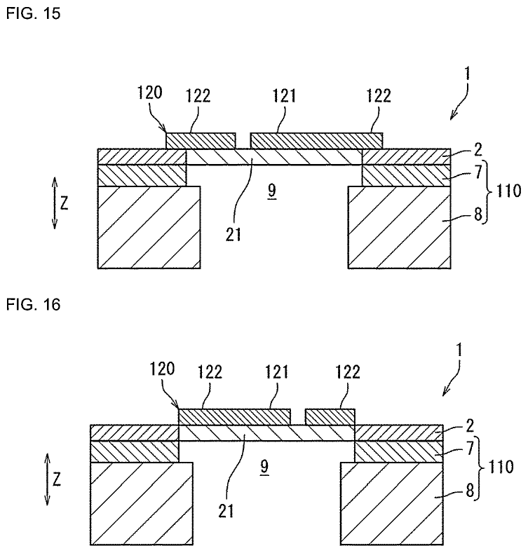

As illustrated in FIGS. 13 to 16, the acoustic wave device 1 includes a support substrate 110 including a hollow portion 9, a piezoelectric layer 2 laminated on the support substrate 110, and an electrode 120 provided on the piezoelectric layer 2. As illustrated in FIGS. 14 to 16, the piezoelectric layer 2 includes a membrane portion 21 at least partially overlapping the hollow portion 9 in the lamination direction (for example, the Z direction) of the support substrate 110 and the piezoelectric layer 2. In FIGS. 13 to 16, the membrane portion 21 of the case where a variation in the boundary region is the maximum is indicated by a solid line. In FIG. 13, the membrane portion 21 of the case where the variation in the boundary region is the minimum is indicated by a two-dot line. The electrode 120 includes an IDT electrode finger 121 and an electrode portion 122 other than the IDT electrode finger 121. The IDT electrode finger 121 is provided on the membrane portion 21 and defines an excitation region 130.

In the present example embodiment, the support substrate 110 includes, for example, a support 8 and a bonding layer 7 provided on the support 8. The piezoelectric layer 2 is provided on the bonding layer 7. The electrode 120 includes a plurality of the IDT electrode fingers 121. The electrode portion 122 other than the IDT electrode finger 121 includes a wiring portion 123 and a busbar portion 124.

As illustrated in FIG. 13, an outer contour of the electrode portion 122 intersects with a boundary of the membrane portion 21 in plan view (in other words, when viewed along the lamination direction Z). In the present example embodiment, the outer contour of the electrode portion 122 includes a linear portion 125. The linear portion 125 intersects with the boundary of the membrane portion 21 at an angle other than 90 degrees in plan view. In other words, the linear portion 125 is configured to be able to intersect with the boundary of the membrane portion 21 at an angle other than 90 degrees, even in the case where the variation in the boundary region of the membrane portion 21 is the maximum or in the case where the variation in the boundary region of the membrane portion 21 is the minimum.

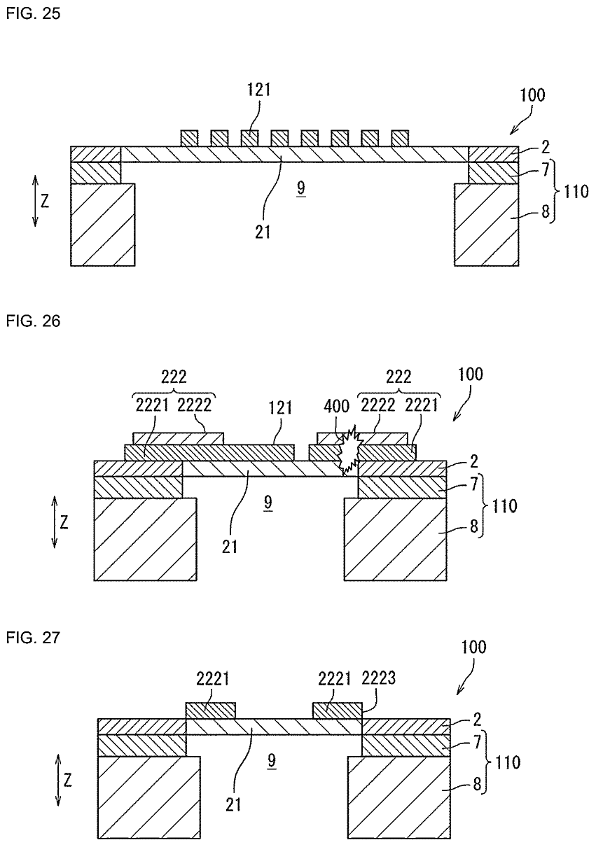

In FIGS. 24 to 27, there is illustrated an acoustic wave device 100, in which an outer contour of an electrode portion 222 other than an IDT electrode finger 121 does not intersect with a boundary of a membrane portion 21 in plan view. In the acoustic wave device 100, the electrode portion 222 includes a first electrode layer 2221 and a second electrode layer 2222 provided on the first electrode layer 2221, and an outer contour of the first electrode layer 2221 defines the outer contour of the electrode portion 222. In the acoustic wave device 100, as an example, the boundary of the membrane portion 21 and the outer contour of the electrode portion 222 extend in parallel and do not intersect with each other in plan view. In the above-discussed acoustic wave device 100, when the boundary region of the membrane portion 21 is widened due to a variation in the manufacturing method and the boundary region of the membrane portion 21 and the electrode portion 222 overlap each other in plan view, a crack 300 may occur in the membrane portion 21 taking a corner (for example, a corner 2223) of the electrode portion 222 as a starting point. Further, the crack 300 may extend along the outer contour of the electrode portion 222 parallel to the boundary of the membrane portion 21, and may cause a fracture 400 of the electrode portion 222.

The acoustic wave device 1 according to an example embodiment of the present disclosure is provided with the support substrate 110 including the hollow portion 9, the piezoelectric layer 2 laminated on the support substrate 110 and including the membrane portion 21 at least partially overlapping the hollow portion 9 in the lamination direction, and the electrode 120 provided on the piezoelectric layer 2. The electrode 120 includes the IDT electrode finger 121 and the electrode portion 122 other than the IDT electrode finger 121. The IDT electrode finger 121 is provided on the membrane portion 21, and the outer contour of the electrode portion 122 intersects with the boundary of the membrane portion 21 in plan view. With this configuration, the acoustic wave device 1 capable of preventing cracks in the membrane portion 21 may be achieved.

In the acoustic wave device 1, the outer contour of the electrode portion 122 includes the linear portion 125, and the linear portion 125 intersects with the boundary of the membrane portion 21 at an angle other than 90 degrees in plan view. With this configuration, even when the boundary region of the membrane portion 21 varies and fluctuates, the membrane portion 21 may be prevented from cracking.

The acoustic wave device 1 of the second example embodiment may be configured as follows.

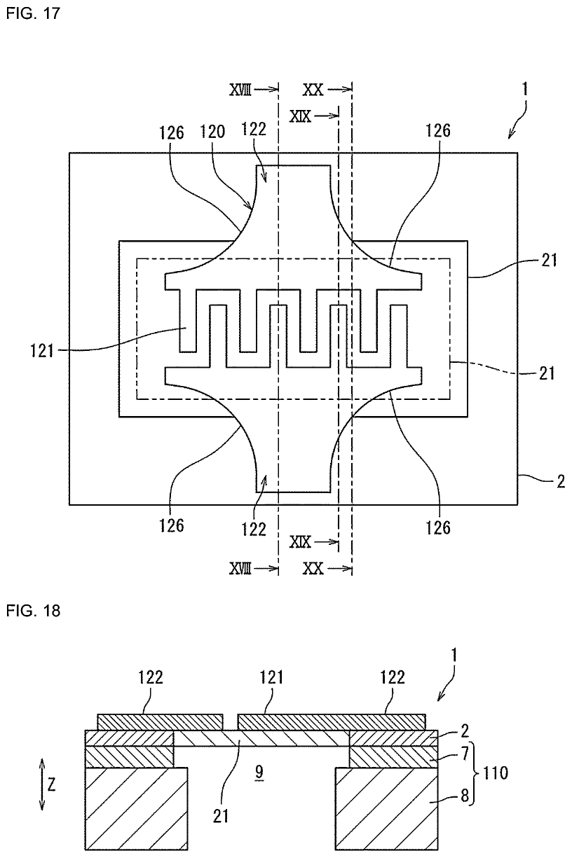

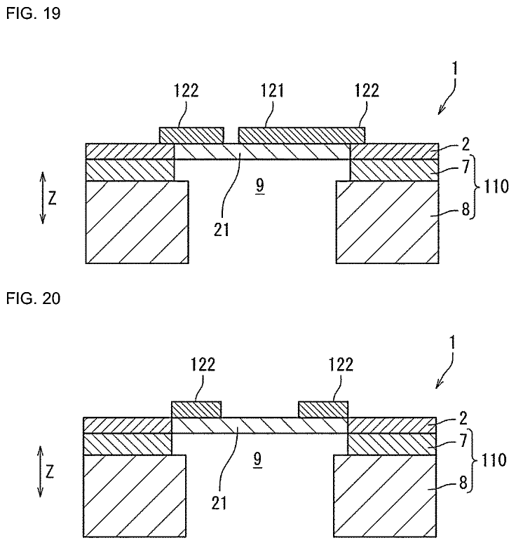

As illustrated in FIGS. 17 to 20, the outer contour of the electrode 120 may include a curved portion 126 instead of the linear portion 125. The curved portion 126 is configured to be able to intersect with the boundary of the membrane portion 21 even in the case where the variation in the boundary region of the membrane portion 21 is the maximum or in the case where the variation in the boundary region of the membrane portion 21 is the minimum. With this configuration, even when the boundary region of the membrane portion 21 varies and fluctuates, the membrane portion 21 may be prevented from cracking.

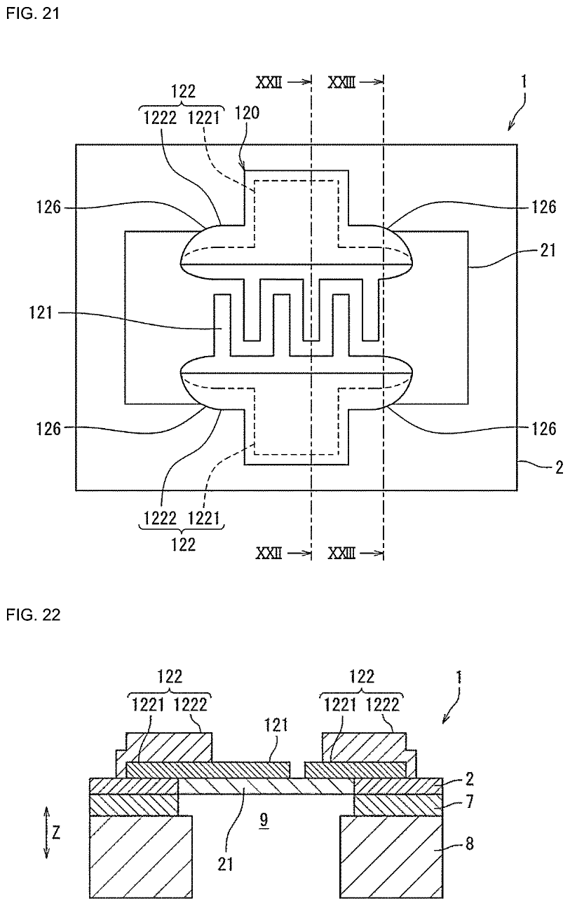

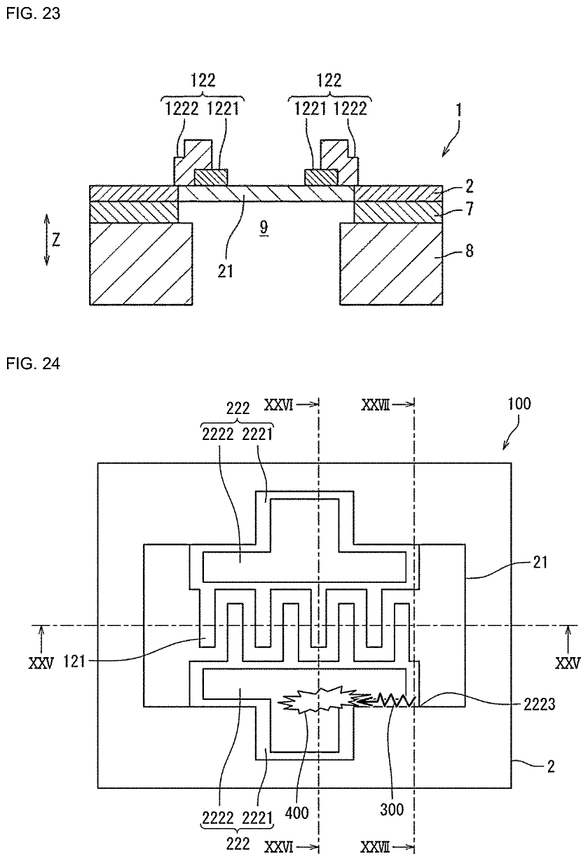

As illustrated in FIGS. 21 to 23, the electrode portion 122 may be configured to include a first electrode layer 1221 and a second electrode layer 1222 provided on the upper surface of the first electrode layer 1221. In this case, in the electrode portion 122 intersecting with the boundary of the membrane portion 21, an outer contour of the second electrode layer 1222 in plan view defines the outer contour of the electrode portion 122. That is, the second electrode layer 1222 covers the first electrode layer 1221, and the outer contour of the second electrode layer 1222 forms the outer contour of the electrode portion 122. For example, by making the second electrode layer 1222 thicker than the first electrode layer 1221, the boundary region of the membrane portion 21 can be pressed by the second electrode layer 1222 thicker than the first electrode layer 1221, whereby cracking of the membrane portion 21 can be prevented more reliably.

In the acoustic wave device 1 of FIGS. 21 to 23, the outer contour of the second electrode layer 1222 includes the curved portion 126, but is not limited thereto, and may include the linear portion 125.

The elastic modulus of the second electrode layer 1222 may be higher than the elastic modulus of the first electrode layer 1221.

The acoustic wave device 1 can be manufactured by any method such as a method of forming the hollow portion 9 by using a sacrificial layer or a method of etching the support 8 and the bonding layer 7 from the back surface.

At least a portion of the configuration of the acoustic wave device 1 of the second example embodiment may be added to the acoustic wave device 1 of the first example embodiment, or at least a portion of the configuration of the acoustic wave device 1 of the first example embodiment may be added to the acoustic wave device 1 of the second example embodiment.

Various example embodiments of the present disclosure have been described in detail with reference to the drawings thus far, and various aspects of the present disclosure will be described at the end.

By optionally combining example embodiments or modifications as appropriate among the various example embodiments or modifications described above, the advantages of the respective example embodiments or modifications can be achieved. Furthermore, combinations of the example embodiments, combinations of the examples, or combinations of the example embodiments and examples can be carried out. In addition, combinations of the features in the different example embodiments or different examples can also be carried out.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support substrate including a hollow portion;
a piezoelectric layer laminated on the support substrate and including a membrane portion at least partially overlapping the hollow portion in the lamination direction; and
an electrode provided on the piezoelectric layer; wherein
the electrode includes an IDT electrode finger and an electrode portion other than the IDT electrode finger;
the IDT electrode finger is provided on the membrane portion; and
an outer contour of the electrode portion intersects with a boundary of the membrane portion in plan view.

2. The acoustic wave device according to claim 1, wherein the outer contour of the electrode portion includes a linear portion that intersects with the boundary of the membrane portion at an angle other than 90 degrees in the plan view.

3. The acoustic wave device according to claim 1, wherein the outer contour of the electrode portion includes a curved portion that intersects with the boundary of the membrane portion in the plan view.

4. The acoustic wave device according to claim 1, wherein
the electrode portion includes a first electrode layer and a second electrode layer provided on an upper surface of the first electrode layer; and
in the electrode portion intersecting with the boundary of the membrane portion, an outer contour of the second electrode layer in the plan view defines the outer contour of the electrode portion.

5. The acoustic wave device according to claim 4, wherein an elastic modulus of the second electrode layer is higher than an elastic modulus of the first electrode layer.

6. The acoustic wave device according to claim 1, wherein the acoustic wave device is configured to generate a plate wave.

7. The acoustic wave device according to claim 1, wherein the acoustic wave device is configured to generate a bulk wave in a thickness-shear mode.

8. The acoustic wave device according to claim 1, wherein the piezoelectric layer includes lithium niobate or lithium tantalate;
the IDT electrode finger includes a first electrode finger and a second electrode finger facing each other in a direction intersecting the lamination direction;
the first electrode finger and the second electrode finger are electrodes adjacent to each other; and
in a case that a thickness of the piezoelectric layer is d and a center-to-center distance between the first electrode finger and the second electrode finger is p, d/p is about 0.5 or less.

9. The acoustic wave device according to claim 8, wherein the d/p is about 0.24 or less.

10. The acoustic wave device according to claim 8,
wherein a metalization ratio MR, which is a ratio of an area of the first electrode finger and the second electrode finger within an excitation region to an area of the excitation region, satisfies a relation of MR≤about 1.75(d/p)+0.075, the excitation region being a region where the first electrode finger and the second electrode finger overlap each other in a direction intersecting the lamination direction.

11. The acoustic wave device according to claim 8,
wherein Euler angles (φ, θ, ψ) of the lithium niobate or the lithium tantalate are in a range of Formula (1), (2), or (3):
(0°±10°, 0° to 20°, optional ψ) Formula (1);
(0°±10°, 20° to 80°, 0° to 60° (1−(θ−50)²/900)^{1/2}) or (0°±10°, 20° to 80°, [180°−60° (1−(θ−50)²/900)^{1/2}] to 180°) Formula (2); and
(0°±10°, [180°−30° (1−(ψ−90)²/8100)^{1/2}] to 180°, optional ψ) Formula (3).

12. The acoustic wave device according to claim 1, wherein the acoustic wave device is configured to generate a Lamb wave.

13. The acoustic wave device according to claim 1, wherein a thickness of the piezoelectric layer is about 50 nm or more and about 1000 nm or less.

14. The acoustic wave device according to claim 13, wherein the acoustic wave device is configured to generate a bulk wave in a thickness-shear primary mode.

15. The acoustic wave device according to claim 1, wherein a center-to-center distance between a first electrode and a second electrode is about 1 μm to about 10 μm.

16. The acoustic wave device according to claim 15, wherein widths of the first electrode and the second electrode are about 150 nm to about 1000 nm.

17. The acoustic wave device according to claim 1, further comprising an insulating layer on the piezoelectric layer.

18. The acoustic wave device according to claim 17, wherein the insulating layer is made of silicon oxide, silicon oxynitride or alumina.

19. The acoustic wave device according to claim 1, further comprising reflectors at both sides of the electrode.
